(19) United States
(12) Patent Application Publication
(10) Pub. No.: US 2026/0261251 A1
(43) Pub. Date: Sep. 3, 2026

(54) ELECTRODE STRUCTURE, PIEZOELECTRIC VIBRATING PIECE, PIEZOELECTRIC DEVICE, AND INTERMEDIATE WAFER FOR MANUFACTURING PIEZOELECTRIC DEVICE

(71) Applicant: NIHON DEMPA KOGYO CO., LTD., Tokyo (JP)

(72) Inventors: Ayako HASHIMOTO, Saitama (JP); Manabu ISHIKAWA, Saitama (JP); Takeru MUTOH, Saitama (JP); Toshiki NAKAMURA, Saitama (JP)

(73) Assignee: NIHON DEMPA KOGYO CO., LTD., Tokyo (JP)

(21) Appl. No.: 19/445,662

(22) Filed: Jan. 12, 2026

(30) Foreign Application Priority Data
Feb. 28, 2025 (JP) 2025-030987

(51) Int. Cl. H03H 9/13; H03B 5/32; H03H 9/15

(52) U.S. Cl. CPC H03H 9/13; H03B 5/32; H03H 9/15

(57) ABSTRACT

An electrode structure includes a molybdenum film and a gold film laminated on the molybdenum film. A piezoelectric vibrating piece includes a substrate having a piezoelectric property and excitation electrodes. The excitation electrodes include molybdenum films as lower layers disposed on a front and a back of the substrate, and gold films laminated on the molybdenum films.

### CROSS-REFERENCE TO RELATED APPLICATIONS

This application is based on and claims priority under 35 U.S.C. § 119 to Japanese Patent Application No. 2025-030987, filed on February 28, 2025, the entire content of which is incorporated herein by reference.

### TECHNICAL FIELD

This disclosure relates to, for example, an electrode structure for use as an excitation electrode for a piezoelectric device, a piezoelectric vibrating piece using the same, a piezoelectric device using this piezoelectric vibrating piece, and an intermediate wafer for use in manufacturing the piezoelectric device.

### DESCRIPTION OF THE RELATED ART

One type of piezoelectric device vibrates in a thickness-shear mode. The piezoelectric device that vibrates in the thickness-shear mode includes a piezoelectric vibrating piece constituted of a piezoelectric piece and excitation electrodes disposed on the front and the back of the piezoelectric piece. A typical example of an electrode structure constituting the excitation electrode is a laminated film formed of a chromium (Cr) film disposed on the piezoelectric piece and a gold film disposed on this chromium film. The chromium film functions as an adhesive layer between the piezoelectric piece and the gold film (for example, paragraph 14 of Japanese Unexamined Patent Application Publication No. 2015-179958).

In association with an increase in communication speed, a higher frequency is being increasingly requested for piezoelectric devices that are reference signal sources of communication devices. In order to achieve a higher frequency for a piezoelectric device that vibrates in a thickness-shear mode and at a fundamental wave, the thickness of a piezoelectric piece becomes thinner and thinner. In association with that, effects of excitation electrodes disposed on the front and the back of the piezoelectric piece on the characteristics of the piezoelectric device pose a problem. Specifically, in the case of a piezoelectric device for high-frequency applications, the resistivity and stress of an electrode film significantly affect the characteristics of the piezoelectric device compared with a piezoelectric device for low-frequency applications. Accordingly, an electrode structure with resistivity and film stress that are as small as possible is desired. An electrode structure constituted of a chromium film and a gold film is not necessarily preferable in view of this demand. While Japanese Unexamined Patent Application Publication No. 2015-179958 describes that an electrode structure including a chromium film and a gold film is improved by disposing a nickel film as an intermediate film between the chromium film and the gold film (for example, paragraph 42 of Japanese Unexamined Patent Application Publication No. 2015-179958), it is not preferable since disposing the intermediate film increases man-hours for manufacturing and costs.

A need thus exists for an electrode structure, a piezoelectric vibrating piece, a piezoelectric device, and an intermediate wafer for manufacturing the piezoelectric device which are not susceptible to the drawback mentioned above.

### SUMMARY

According to an aspect of this disclosure, there is provided an electrode structure including a molybdenum film and a gold film laminated on the molybdenum film.

### BRIEF DESCRIPTION OF THE DRAWINGS

The foregoing and additional features and characteristics of this disclosure will become more apparent from the following detailed description considered with reference to the accompanying drawings, wherein:

FIGS. 1A and 1B are drawings for describing respective embodiments of the disclosure of an electrode structure and a piezoelectric vibrating piece;

FIGS. 2A and 2B are drawings for describing an experiment that found respective requirements for the disclosure of the electrode structure and the piezoelectric vibrating piece and the results thereof;

FIGS. 3A and 3B are drawings for describing an embodiment of the disclosure of a piezoelectric device;

FIGS. 4A to 4D are drawings for describing an exemplary method for manufacturing a piezoelectric vibrating piece and an intermediate wafer for manufacturing the piezoelectric device; and

FIGS. 5A and 5B are drawings for describing a piezoelectric vibrating piece of a modification.

### DETAILED DESCRIPTION

The following describes each embodiment of the disclosure of this application with reference to the drawings. Note that each drawing used for the description is merely shown schematically to the extent necessary for understanding this disclosure. In each drawing used for the description, identical reference numerals are attached to similar components, and the explanations thereof may be omitted. Shapes, dimensions, materials, and the like described in the following explanations are merely exemplary examples within the scope of this disclosure. Therefore, this disclosure is not limited to only the following embodiments.

### Embodiments of Electrode Structure and Piezoelectric Vibrating Piece

### 1-1. Configuration

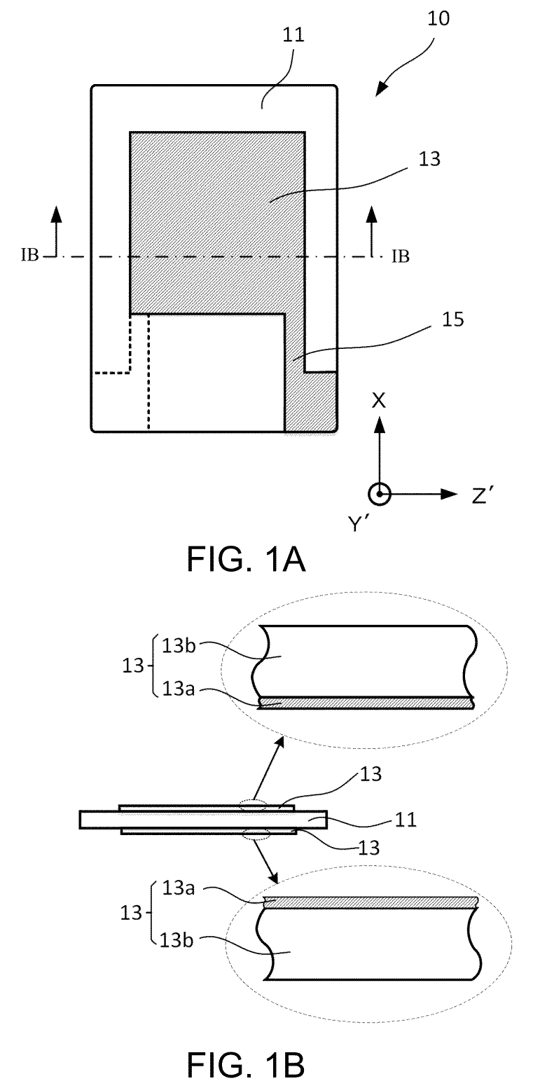

FIGS. 1A and 1B are explanatory drawings of a piezoelectric vibrating piece 10 as respective embodiments of an electrode structure according to a first aspect and a piezoelectric vibrating piece according to a second aspect. In particular, FIG. 1A is a plan view of the piezoelectric vibrating piece 10, and FIG. 1B is a sectional drawing of the piezoelectric vibrating piece 10 taken along the line IB-IB in FIG. 1A. In FIG. 1B, enlarged views of parts of an excitation electrode are also shown.

The piezoelectric vibrating piece 10 of the embodiment is an example of applying the present disclosure to an AT-cut crystal element. Coordinate axes X, Y', Z' in FIG. 1A are axes derived from crystallographic axes of crystal. The prime symbols on Y' and Z' mean that the axes are shifted corresponding to the cut angles of an AT-cut from the Y-axis and the Z-axis as original crystallographic axes of the crystal.

The piezoelectric vibrating piece 10 of the embodiment includes an AT-cut crystal element 11 as a substrate having a piezoelectric property, excitation electrodes 13 disposed on respective principal surfaces on the front and the back of the crystal element 11 and constituted of molybdenum films 13a as lower layers and gold films 13b laminated on these molybdenum films, and extraction electrodes 15. The molybdenum film 13a as the lower layer functions as an adhesive layer between the crystal element 11 and the gold film 13b.

The film thickness of the molybdenum film 13a may be any given preferred thickness corresponding to the design of a piezoelectric device. However, when the film thickness of the molybdenum film 13a is too thin, the function as the adhesive layer is not obtained, and when the film thickness of the molybdenum film 13a is too thick, the proportion of an electrode mass and/or a film stress may be increased in a piezoelectric device with high frequency, thereby being unpreferable. Taking these into consideration, the film thickness of the molybdenum film 13a should be 0.5 nm or more and 5 nm or less, preferably 0.5 nm or more and 3 nm or less, more preferably 0.5 nm or more and 2 nm or less, and further preferably 0.5 nm or more and 1 nm or less.

The film thickness of the gold film 13b should be, for example, 10 nm or more and 100 nm or less, furthermore, should be 10 nm or more and 60 nm or less from the standpoint of reducing the use of gold, and should be 30 nm or more and 70 nm or less from the standpoint of reducing the use of gold and reducing resistivity.

The reason that the film thickness of the molybdenum film 13a and the film thickness of the gold film 13b should be the respective values described above will be described in the section of the experiment described later.

In the case of the piezoelectric vibrating piece 10 of the embodiment, the crystal element 11 has a planar shape in a quadrilateral shape, and here, is an AT-cut crystal element in a rectangular shape. The thickness (dimension in the Y'-direction) of the crystal element 11 is a predetermined thickness corresponding to an oscillation frequency required for the piezoelectric vibrating piece 10. Accordingly, as the piezoelectric vibrating piece 10 becomes designed for higher-frequency applications, the thickness of the crystal element 11 becomes thinner. The thinner the thickness of the piezoelectric vibrating piece becomes due to the piezoelectric vibrating piece 10 becoming designed for high-frequency applications, the more important the configuration of the molybdenum film 13a and the gold film 13b of the excitation electrode 13 becomes, and therefore, the numerical values such as the above-described film thicknesses become effective.

In this embodiment, the excitation electrode 13 also has a planar shape in a quadrilateral shape similarly to the crystal element 11. The extraction electrode 15 is extracted from a part of the excitation electrode 13 to one end of the crystal element 11. The extraction electrode 15 is made of the same material as that of the excitation electrode 13 and is an integrally formed film.

Note that the planar shape of the crystal element and the planar shape of the excitation electrode are not limited to the quadrilateral shape, may be changed corresponding to the design of the piezoelectric vibrating piece 10, and therefore, may be a circular shape or an elliptical shape. The planar shape of the crystal element and the planar shape of the excitation electrode may be different.

### 1-2. Experiment

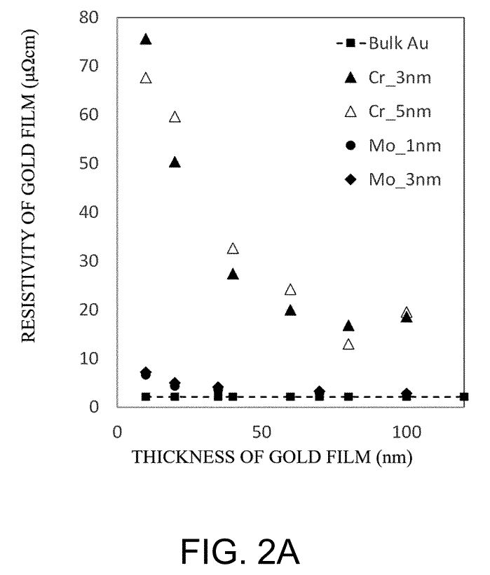

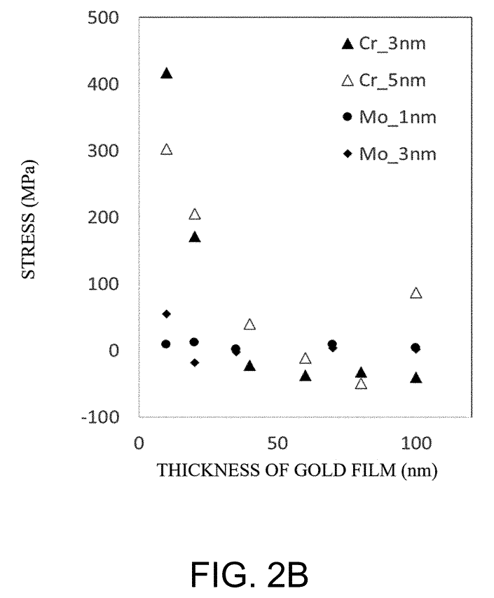

The reason that the film thickness of the molybdenum film 13a and the film thickness of the gold film 13b are the respective values described above is based on an experiment by the inventors relating to this application. This will be described below with reference to FIG. 2A and FIG. 2B.

### 1-2-1. Examination of Resistivity

The inventors relating to this application prepared a plurality of substrates, specifically, a plurality of AT-cut crystal substrates, divided them into groups, and formed molybdenum films by sputtering on each of the substrates in each group to have different film thicknesses, specifically, film thicknesses of 1 nm, 3 nm, and 5 nm.

On the molybdenum films of the substrates in respective groups after the completion of molybdenum film formation, gold films were formed by sputtering at a plurality of thickness levels ranging from 10 nm to 100 nm, specifically, at thicknesses of 10 nm, 20 nm, 40 nm, 60 nm, 80 nm, and 100 nm.

The respective substrates after the completion of gold film formation were heat treated at a temperature of 300ºC and in a nitrogen atmosphere, assuming heat in a hardening process performed when a piezoelectric vibrating piece is fixed to a piezoelectric device container with a conductive adhesive.

Samples having only molybdenum films were fabricated by a procedure similar to the above except that only the molybdenum films were formed on the substrates.

Next, respective resistivities of the films were measured for the samples in which the molybdenum films and the gold films were formed and the samples in which only the molybdenum films were formed.

Next, a parallel resistance model was assumed from the samples in which the molybdenum films and the gold films were formed and the samples in which only molybdenum films were formed, and the resistivities of the gold films were calculated using the resistivities of both the samples. Here, the reason for calculating the resistivities of the gold films was to grasp whether the resistivities of the gold films were changed or not due to the occurrence of diffusion or the like of the molybdenum films to the gold films and a degree of effect when the resistivities were changed.

Samples of Comparative Examples were fabricated by a procedure similar to the fabrication procedures of the samples with the molybdenum films and the gold films and the samples with only the molybdenum films except that chromium films were formed to have film thicknesses of 3 nm and 5 nm instead of the molybdenum films on the substrates as the samples of Comparative Examples. The resistivities of the gold films of the samples of Comparative Examples were also calculated using a parallel resistance model similar to the above.

As references, only gold films were formed at a plurality of thickness levels ranging from 10 nm to 100 nm on the substrates, and respective resistivities were measured.

FIG. 2A is a characteristic diagram summarizing the tendency of resistivity of the gold film with respect to the thickness of the molybdenum film and/or the thickness of the gold film of each of the various kinds of the experiment samples using the molybdenum films and formed as described above, the samples of Comparative Examples formed using the chromium films, and the reference samples using only the gold films. Note that the dashed line (Bulk Au) in FIG. 2A is the characteristic of the reference sample.

Note that the resistivity of the gold film of the sample having the molybdenum film with the 5 nm film thickness was substantially the same as that of the sample having the molybdenum film with the 3 nm film thickness, and therefore, the resistivity of the sample having the molybdenum film with the 5 nm film thickness is not plotted in FIG. 2A.

From FIG. 2A, it is seen that using the molybdenum film as the lower layer (adhesive film) allows for making the resistivity of the gold film smaller than using the chromium film. Specifically, when the sample uses the chromium film as the lower layer and the thickness of the gold film is 50 nm or less, the resistivity of the gold film is at least approximately 30 μΩ·cm, and at most approximately 80 μΩ·cm. Even when the sample uses the chromium film as the lower layer and the thickness of the gold film is increased, the resistivity of the gold film is at least approximately 15 μΩ·cm. In contrast to this, when the sample uses the molybdenum film as the lower layer, irrespective of the film thickness of the gold film, the resistivity of the gold film is less than 10 μΩ·cm, and when the film thickness of the gold film is 40 nm or more, the resistivity of the gold film is as small as less than 5 μΩ·cm.

The reason that using the molybdenum film as the lower layer (adhesive film) allows for making the resistivity of the gold film smaller than using the chromium film is assumed to be that the diffusion of the molybdenum to the gold film is substantially absent, which allows for inhibiting fluctuations in the physical properties and the like of the gold film.

Here, in a crystal unit as a piezoelectric device, considering an example of a crystal unit with a frequency of, for example, 48 MHz, which is heavily used as a reference clock source, the film thickness of the gold film is approximately 150 nm, and its resistivity is approximately 20 μΩ·cm. Furthermore, the resistivity of the gold film included in the excitation electrode of the crystal unit for high-frequency applications is preferably 20 μΩ·cm or less. Examining the characteristic diagram in FIG. 2A from such an aspect, the following (a) to (d) can be said.
(a). While mentioned above, using the molybdenum film as the lower layer (adhesive film) allows for obtaining an electrode film with a smaller resistivity than using the chromium film.
(b). Using the molybdenum film as the lower layer allows the gold film to have a resistivity of 8 to 3 μΩ·cm irrespective of the thickness of the gold film. Moreover, this tendency is obtainable in any case where the thickness of the molybdenum film is 1 nm, 3 nm, or 5 nm, which is omitted from illustration.
(c). From the respective matters described above, while the film thickness of the molybdenum film should be 5 nm or less, the minimum necessary thickness of the molybdenum film can reduce material costs and manufacturing man-hours. Therefore, the thickness of the molybdenum film should be 0.5 nm or more and 5 nm or less, more preferably 0.5 nm or more and 3 nm or less, and further preferably 0.5 nm or more and 2 nm or less. In addition, when the case where the laminated film of the molybdenum film and the gold film is formed by a photolithography technique and a metal etching technique is considered and a reduction in the side etching amount of the molybdenum film, in other words, a reduction of the formation of an eaves-shaped gold film on the molybdenum film is considered, the film thickness of the molybdenum film should also be the minimum necessary, and therefore, for example, the film thickness of the molybdenum film may be 0.5 nm or more and 1 nm or less.
   Note that the reason for the lower limit of the film thickness of the molybdenum film 13a being 0.5 nm is that when the film thickness of the molybdenum film 13a is smaller than 0.5 nm, it is considered that feasibility as a film is low and the adhesive function to the substrate as the lower layer film is not obtainable.
(d). On the other hand, the gold film with a thickness of 10 nm to 100 nm provides a proper resistivity in this experiment. Moreover, when the thickness of the gold film is 20 nm or more, the resistivity of the gold film is reduced to less than 5 μΩ·cm. When the thickness of the gold film is thick, the material cost increases, which is unpreferable, and therefore, it is considered that the thickness of the gold film should be 10 nm to 100 nm, preferably 10 nm to 70 nm. Considering that the material cost of gold can be reduced, the resistivity of the gold film can be less than 5 μΩ·cm, and the mass of the electrode should be small for piezoelectric devices for high-frequency applications, it is believed that the gold film preferably has a thickness of 30 nm to 70 nm.

### 1-2-2. Examination of Stress

Next, a relationship between the film thickness of the molybdenum film in the electrode structure of the present disclosure and a stress of the electrode structure will be examined. FIG. 2B is a drawing summarizing experimental results of examining relationships between the film thicknesses of the molybdenum films and the stresses in the electrode structure of the above-described embodiment, and is a drawing indicating the film thickness of the gold film on the horizontal axis and the stress in the electrode structure on the vertical axis. Note that the stress in the electrode structure when the film thickness of the molybdenum film was 5 nm was substantially the same as that of the sample having the molybdenum film with the 3 nm film thickness, and therefore, the stress in the electrode structure when the film thickness of the molybdenum film was 5 nm is not plotted in FIG. 2B. FIG. 2B also shows the results of the stresses of the samples made similarly to that of Example except that the lower layers were chromium films with the thicknesses of 3 nm and 5 nm as Comparative Examples.

In FIG. 2B, the positive direction on the vertical axis is a tensile stress, and the negative direction is a compressive stress. In the case of the piezoelectric vibrating piece, an oscillation frequency fluctuates due to stress relaxation over time when a stress occurs in the electrode structure, and therefore, a small stress in the electrode structure is preferred. Examining the characteristic diagram in FIG. 2B from such an aspect, the following can be said.

When the lower layer is the molybdenum film, the stress in the electrode structure is in the range of ±50 MPa in any case where the thickness of the molybdenum film is 1 nm, 3 nm, or 5 nm, which is omitted from illustration. In contrast to this, when the lower layer is the chromium film, the stress in the electrode structure is large compared with the case where the lower layer is the molybdenum film, and in particular, when the film thickness of the gold film is 40 nm or less, the stress in the electrode structure increases to 200 MPa to 400 MPa.

From the above-described examination relating to the stress, the thickness of the molybdenum film should be 0.5 nm or more and 5 nm or less, more preferably 0.5 nm or more and 3 nm or less, and further preferably 0.5 nm or more and 2 nm or less or 1 nm or less. The thickness of the gold film should be 10 nm to 100 nm, preferably 10 nm to 70 nm, and more preferably 30 nm to 70 nm.

Note that, in each of the disclosures of the electrode structure and the piezoelectric vibrating piece, the film thickness of the molybdenum film is a thin film of several nm, or 0.5 nm at the minimum level. Examples of methods of identifying such a film thickness can include, for example, XPS depth profiling, X-ray reflectivity (XRR), cross-sectional TEM, and the like.

### Embodiment of Piezoelectric Device

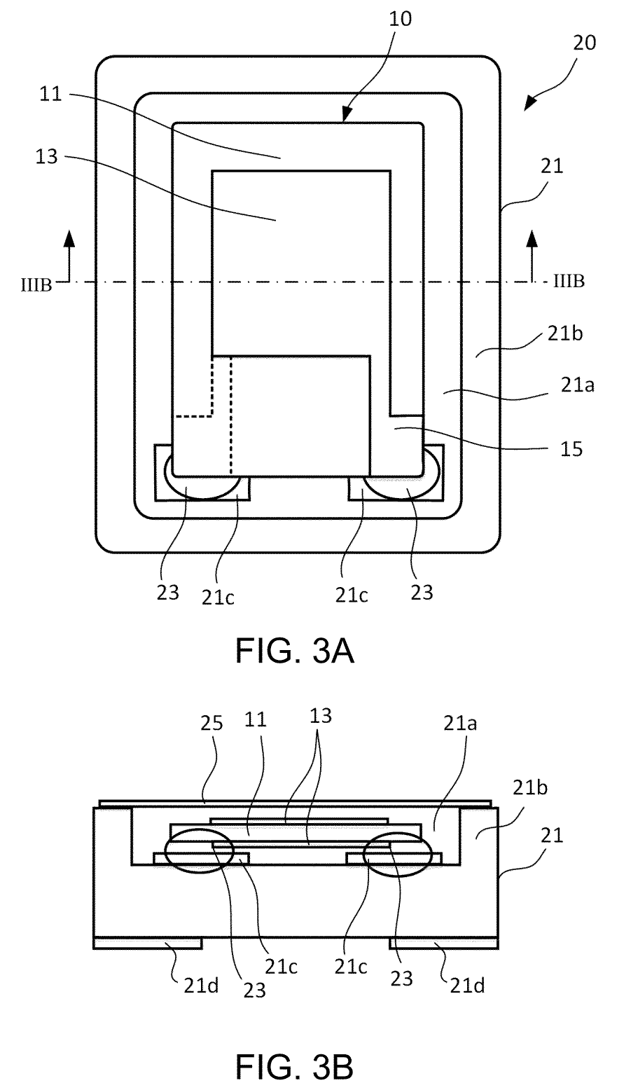

Next, an embodiment of the disclosure of the piezoelectric device will be described. Here, an example in which a crystal unit is used as the piezoelectric device will be described. FIGS. 3A and 3B are explanatory drawings therefor. In particular, FIG. 3A is a plan view of a piezoelectric device 20 of the embodiment, and FIG. 3B is a sectional drawing of the piezoelectric device 20 taken along the line IIIB- IIIB in FIG. 3A. In FIG. 3A, a lid member 25 included in the piezoelectric device 20 is not illustrated.

A crystal unit 20 as the piezoelectric device 20 of the embodiment includes the piezoelectric vibrating piece 10 according to the first aspect and a container 21 housing this piezoelectric vibrating piece 10.

The container 21 in the case of this example includes a depressed portion 21a in a quadrilateral shape in plan view for housing the piezoelectric vibrating piece 10, a dike 21b surrounding the depressed portion 21a, an adhesion pad 21c to which the piezoelectric vibrating piece 10 is fixedly adhered, and an external connection terminal 21d that is disposed on an external bottom surface of the container 21 and connects the piezoelectric device 20 to any electronic equipment. The adhesion pad 21c and the external connection terminal 21d are electrically connected via a via-wiring or a castellation (not illustrated). This container 21 can be constituted of a known ceramic package.

The piezoelectric vibrating piece 10 has a cantilever support structure in this case. Accordingly, the piezoelectric vibrating piece 10 is connected and fixed to the adhesion pad 21c of the container 21 at the position of the extraction electrode 15 via a conductive adhesive 23. The dike 21b of the container 21 has a top surface on which the lid member 25 is bonded in a structure corresponding to a sealing method, and the piezoelectric vibrating piece 10 is sealed in the container 21.

Note that while the example in which the crystal unit is used as the piezoelectric device has been described in the above-described embodiment of the piezoelectric device, a piezoelectric device having a quartz-crystal vibrating piece and other electronic components, such as a temperature sensor and an oscillator circuit, mounted inside the container 21, that is, a temperature-sensor-provided crystal unit and a crystal controlled oscillator (also including one with a temperature compensation function) are also included in the electronic device of the present disclosure. The above-described structure of the container 21 is merely an example, and the structure of the container and the like may be other any given preferred structures.

### Method for Manufacturing Piezoelectric Vibrating Piece and Intermediate Wafer for Forming Piezoelectric Device

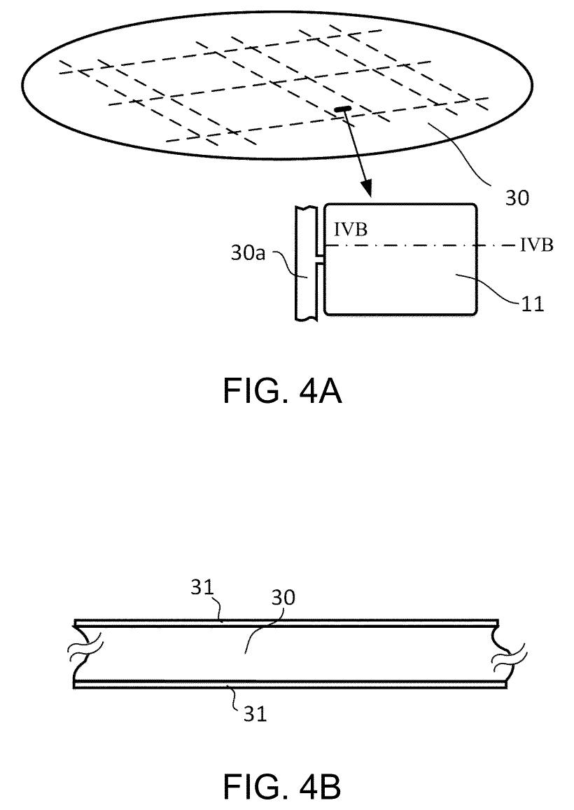

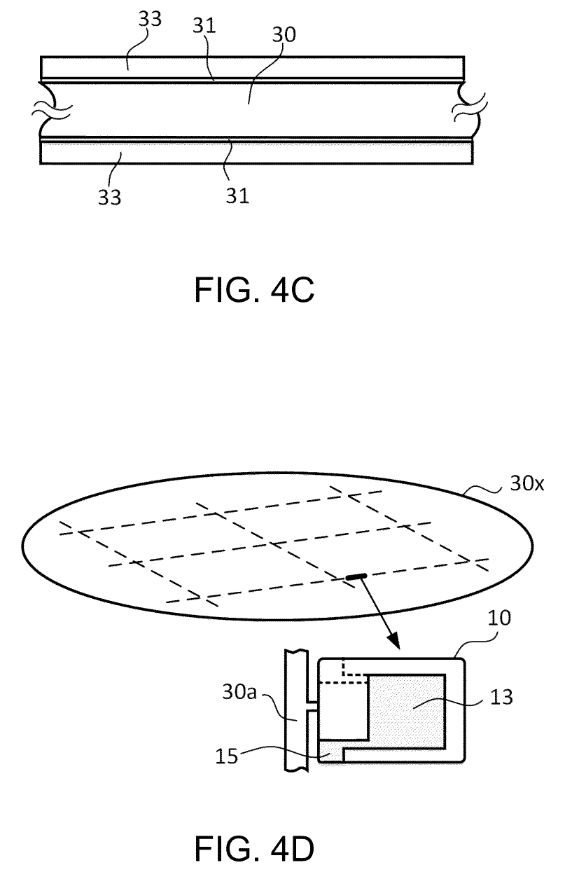

Next, one example of a method for manufacturing the electrode structure according to the first aspect and the piezoelectric vibrating piece according to the second aspect, and an embodiment of an intermediate wafer for the piezoelectric device as a fourth aspect will be described. FIG. 4A to FIG. 4D are relevant portions of a manufacturing process flowchart therefor. Note that FIG. 4B and FIG. 4C are wafer sectional drawings during the manufacturing process, and are sectional drawings at a cross-sectional position taken along the line IVB-IVB in FIG. 4A. Note that this example is also described using a quartz-crystal vibrating piece as an example of the piezoelectric vibrating piece.

First, an AT-cut crystal wafer 30 is prepared (FIG. 4A). Next, this crystal wafer 30 is subjected to an outer shape process for the piezoelectric vibrating piece by a known photolithography technique and wet etching technique, and the wafer 30 having a plurality of the crystal elements 11 each connected to a frame 30a at one end is formed (FIG. 4A).

Next, molybdenum films 31 are formed to have a value within the film thickness range of the requirement according to the first aspect, for example, a film thickness of 1 nm on the front and the back of the crystal wafer 30 on which the formation of the crystal elements 11 has been completed by any given preferred film forming method (FIG. 4B).

Next, gold films 33 are formed to have a value within the film thickness range of the requirement according to the first aspect, for example, a film thickness of 60 nm on these molybdenum films 31 by any given preferred film forming method (FIG. 4C).

Next, the molybdenum films 31 and the gold films 33 are patterned into the shape of the excitation electrode 13 and the extraction electrode 15 by a known photolithography technique and metal etching technique (FIG. 4D).

These processes allow for manufacturing the piezoelectric vibrating piece 10, and moreover, allow for obtaining an intermediate wafer 30x (see FIG. 4D) for forming the piezoelectric device that includes a plurality of the piezoelectric vibrating pieces 10 for manufacturing the piezoelectric device in a matrix.

Note that this disclosure may be modified in any suitable manner. While in the above-described embodiment, the crystal wafer has a planar shape in a circular shape, the planar shape of the crystal wafer may be another shape, such as a quadrilateral shape. The crystal wafer is not limited to an AT-cut one, and may be a twice rotated crystal wafer typified by an SC-cut.

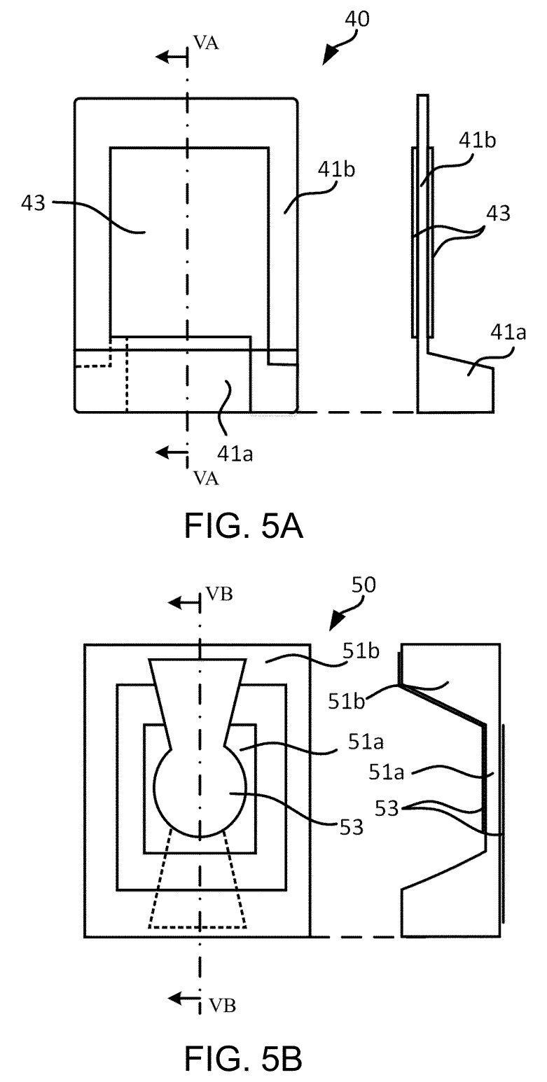

While in the above-described embodiment, the piezoelectric vibrating piece uses the flat-plate crystal element illustrated in FIGS. 1A and 1B, the shape of the piezoelectric vibrating piece is not limited to this. For example, a piezoelectric vibrating piece 40 as illustrated in the plan view and the sectional drawing taken along the line VA-VA in FIG. 5A is allowed. That is, the piezoelectric vibrating piece 40 may include a thick portion 41a that is partly thick, a vibrator 41b having a predetermined thickness corresponding to a frequency, and excitation electrodes 43 according to the present disclosure disposed on the front and the back of the vibrator 41b.

For example, a piezoelectric vibrating piece 50 as illustrated in the plan view and the sectional drawing taken along the line VB-VB in FIG. 5B is also allowed. That is, the piezoelectric vibrating piece 50 may include a vibrator 51a having a predetermined thickness corresponding to a frequency, a thick portion 51b surrounding this vibrator 51a from four sides, and excitation electrodes 53 according to the present disclosure disposed on the front and the back of the vibrator 51a.

An electrode structure according to a first aspect of this application is an electrode structure including a molybdenum film and a gold film laminated on this molybdenum film.

Here, "including" means that a film of another material may be included on the premise that the molybdenum film and the gold film are in contact. That is, it means that there may be three layers or more. Typically, however, the electrode structure according to the first aspect is constituted of the molybdenum film as the lower layer and the gold film laminated thereon.

A piezoelectric vibrating piece according to a second aspect of this application includes a substrate having a piezoelectric property and the electrode structures according to the first aspect disposed on the front and the back of this substrate.

A piezoelectric device according to a third aspect of this application includes the piezoelectric vibrating piece according to the second aspect and a container containing this piezoelectric vibrating piece.

Here, the piezoelectric device is a piezoelectric resonator, a piezoelectric oscillator, a piezoelectric resonator with a temperature sensor, a piezoelectric oscillator with a temperature compensation function, or the like, and the typical example is a crystal unit (also including one with a temperature sensor), a crystal controlled oscillator (also including one with a temperature compensation function), or the like that vibrates in a thickness-shear mode typified by an AT-cut crystal unit.

An intermediate wafer for manufacturing a piezoelectric device according to a fourth aspect of this application is a wafer having a piezoelectric property and a wafer including a plurality of the piezoelectric vibrating pieces according to the second aspect described above in a matrix. In this fourth aspect, the wafer having a piezoelectric property is a wafer made of a material having a piezoelectric property, such as crystal, lithium niobate, and lithium tantalate, and typically, is a crystal wafer for a crystal unit that vibrates in a thickness-shear mode typified by an AT-cut crystal wafer.

The electrode structure according to the first aspect of this application includes the molybdenum film and the gold film laminated on this molybdenum film, and therefore, an electrode structure that exhibits desired resistivity and stress is achievable as is clear from the experimental results described above. Accordingly, use as an electrode for various kinds of electronic components including, for example, the piezoelectric device is expectable.

The piezoelectric vibrating piece according to the second aspect of this application includes the electrode structure according to the first aspect, and therefore, achieving a piezoelectric vibrating piece with improved characteristics compared with conventional ones is expectable.

The piezoelectric device according to the third aspect of this application uses the piezoelectric vibrating piece according to the second aspect, and therefore, achieving a piezoelectric device with improved characteristics compared with conventional ones, for example, a piezoelectric device for high-frequency applications having an oscillation frequency on the order of several hundred MHz is expectable.

The intermediate wafer for manufacturing the piezoelectric device according to the fourth aspect of this application includes the plurality of piezoelectric vibrating pieces according to the second aspect in a matrix, and therefore, the piezoelectric device according to the third aspect is producible with good mass productivity by mounting a piezoelectric vibrating piece diced from this wafer in a container.

The principles, exemplary embodiment and mode of operation of the present disclosure have been described in the foregoing specification. However, the disclosure which is intended to be protected is not to be construed as limited to the particular embodiments disclosed. Further, the embodiments described herein are to be regarded as illustrative rather than restrictive. Variations and changes may be made by others, and equivalents employed, without departing from the spirit of the present disclosure. Accordingly, it is expressly intended that all such variations, changes and equivalents which fall within the spirit and scope of the present disclosure as defined in the claims, be embraced thereby.

What is claimed is:

1. An electrode structure comprising:
a molybdenum film; and
a gold film laminated on the molybdenum film.

2. The electrode structure according to claim 1, wherein
the electrode structure is constituted of a molybdenum film and a gold film laminated on the molybdenum film.

3. The electrode structure according to claim 1, wherein
the molybdenum film has a film thickness of 0.5 nm or more and 5 nm or less.

4. The electrode structure according to claim 1, wherein
the gold film has a film thickness of 10 nm or more and 100 nm or less.

5. The electrode structure according to claim 1, wherein
the molybdenum film has a film thickness of 0.5 nm or more and 5 nm or less, and
the gold film has a film thickness of 10 nm or more and 100 nm or less.

6. The electrode structure according to claim 1, wherein
the molybdenum film has a film thickness of 0.5 nm or more and 3 nm or less, and
the gold film has a film thickness of 30 nm or more and 70 nm or less.

7. A piezoelectric vibrating piece comprising:
a substrate having a piezoelectric property; and
excitation electrodes including molybdenum films as lower layers disposed on a front and a back of the substrate, and gold films laminated on the molybdenum films.

8. The piezoelectric vibrating piece according to claim 7, wherein
the excitation electrode is constituted of a molybdenum film and a gold film laminated on the molybdenum film.

9. The piezoelectric vibrating piece according to claim 7, wherein
the molybdenum film has a film thickness of 0.5 nm or more and 5 nm or less.

10. The piezoelectric vibrating piece according to claim 7, wherein
the gold film has a film thickness of 10 nm or more and 100 nm or less.

11. The piezoelectric vibrating piece according to claim 7, wherein
the molybdenum film has a film thickness of 0.5 nm or more and 5 nm or less, and
the gold film has a film thickness of 10 nm or more and 100 nm or less.

12. The piezoelectric vibrating piece according to claim 7, wherein
the molybdenum film has a film thickness of 0.5 nm or more and 3 nm or less, and
the gold film has a film thickness of 30 nm or more and 70 nm or less.

13. The piezoelectric vibrating piece according to claim 7, wherein
the piezoelectric vibrating piece is an AT-cut crystal element.

14. A piezoelectric device comprising:
the piezoelectric vibrating piece according to claim 7; and
a container containing the piezoelectric vibrating piece.

15. The piezoelectric device according to claim 14, wherein
the piezoelectric device is a crystal unit, a temperature-sensor-provided crystal unit, a crystal controlled oscillator, or a crystal controlled oscillator with a temperature compensation function.

16. An intermediate wafer for manufacturing a piezoelectric device, comprising
a piezoelectric substrate including a plurality of the piezoelectric vibrating pieces according to claim 7 in a matrix.

17. The intermediate wafer for manufacturing the piezoelectric device according to claim 16, wherein
the piezoelectric vibrating piece is a quartz-crystal vibrating piece, and
the intermediate wafer is a crystal wafer.

18. The intermediate wafer for manufacturing the piezoelectric device according to claim 16, wherein
the piezoelectric vibrating piece is an AT-cut quartz-crystal vibrating piece, and
the intermediate wafer is an AT-cut crystal wafer.
